(19) United States
(12) Patent Application Publication
(10) Pub. No.: US 2014/0366804 A1
(43) Pub. Date: Dec. 18, 2014

(54) Performing Atomic Layer Deposition on Large Substrate Using Scanning Reactors

(71) Applicant: Veeco ALD Inc., Fremont, CA (US)

(72) Inventors: Samuel S. Pak, San Ramon, CA (US); Hyoseok Daniel Yang, Sunnyvale, CA (US); Sang In Lee, Sunnyvale, CA (US)

(21) Appl. No.: 14/298,654

(22) Filed: Jun. 6, 2014

Related U.S. Application Data
(60) Provisional application No. 61/835,436, filed on Jun. 14, 2013.

(51) Int. Cl. C23C 16/455

(52) U.S. Cl. CPC C23C 16/45551; C23C 16/45536; C23C 16/45553
USPC 118/718; 118/715; 118/723 R; 118/729

(57) ABSTRACT

Embodiments relate to a deposition device for depositing one or more layers of material on a substrate using scanning modules that move across the substrate in a chamber filled with reactant precursor. The substrate remains stationary during the process of depositing the one or more layers of material. A chamber enclosing the substrate is filled with reactant precursor to expose the substrate to the reactant precursor. As the scanning modules move across the substrate, the scanning modules remove the reactant precursor in their path and/or revert the reactant precursor to an inactive state. The scanning modules also inject source precursor onto the substrate as the scanning modules move across the substrate.

### CROSS-REFERENCE TO RELATED APPLICATIONS

This application claims priority under 35 U.S.C. §119(e) to co-pending U.S. Provisional Patent Application No. 61/835,436, filed on Jun. 14, 2013, which is incorporated by reference herein in its entirety.

This application is related to U.S. patent application Ser. No. 12/539,477 filed on Aug. 11, 2009 (now issued as U.S. Pat. No. 8,470,718), which is incorporated by reference herein in its entirety.

### BACKGROUND

The present disclosure relates to performing atomic layer deposition (ALD) using one or more scanning modules that inject materials onto a substrate.

An atomic layer deposition (ALD) is a thin film deposition technique for depositing one or more layers of material on a substrate. ALD uses two types of chemical, one is a source precursor and the other is a reactant precursor. Generally, ALD includes four stages: (i) injection of a source precursor, (ii) removal of a physical adsorption layer of the source precursor, (iii) injection of a reactant precursor, and (iv) removal of a physical adsorption layer of the reactant precursor.

ALD can be a slow process that can take an extended amount of time or many repetitions before a layer of desired thickness can be obtained. Hence, to expedite the process, a vapor deposition reactor with a unit module (so-called a linear injector), as described in U.S. Patent Application Publication No. 2009/0165715 or other similar devices may be used to expedite ALD process. The unit module includes an injection unit and an exhaust unit for a source material (a source module), and an injection unit and an exhaust unit for a reactant (a reactant module).

### SUMMARY

Embodiments are related to an apparatus for depositing material on a substrate by using a stationary injector to inject a first precursor and a scanning module to inject a second precursor onto the substrate. The scanning module is configured to move across space between the stationary injector and the substrate to inject the second precursor onto the one or more substrates. An enclosure is provided to enclose the susceptor and the scanning module.

In one embodiment, at least another scanning module is provided to move across the space between the stationary injector and the one or more substrates to inject a third precursor onto the one or more substrate.

In one embodiment, the scanning module is formed with a first gas exhaust, a gas injector, and a second gas exhaust. The first gas exhaust discharges the first precursor present between the scanning module and the substrate. The gas injector injects the second precursor onto the substrate. The second gas exhaust discharges excess second precursor remaining after injection of the second precursor onto the substrate.

In one embodiment, the scanning module is further formed with a purge gas injector to inject purge gas to remove physisorbed second precursor from the substrate.

In one embodiment, the purge gas further prevents the second precursor from coming into contact with the first precursor in areas other than on the substrate.

In one embodiment, the first precursor is reactant precursor for performing atomic layer deposition, and the second precursor is source precursor for performing the atomic layer deposition.

In one embodiment, a radical generator is provided to connect to the stationary injector. The radical generator generates radicals of gas as reactant precursor.

In one embodiment, the scanning module further includes one or more neutralizers at least at a leading edge or a trailing edge to render the radicals of gas inactive.

In one embodiment, the scanning module includes a plurality of bodies formed with a gas injector to inject gas onto the substrate. The bodies are connected by bridge portions. Each of the bridge portions is formed with an opening to expose the substrate to the first precursor.

In one embodiment, each of the bodies is formed with a first precursor exhaust slated towards the opening to discharge the first precursor entering through the opening.

In one embodiment, an upper surface of each of the bodies is curved towards a bottom surface of the body at an edge adjacent to the opening.

In one embodiment, the substrate remains stationary during the injection of the first precursor or the second precursor.

In one embodiment, the susceptor is formed with pathways at both ends to discharge the second precursor injected onto the susceptor by the scanning module.

In one embodiment, one or more rails are provided so that the scanning modules can slide across the substrate.

In one embodiment, the susceptor is a conveyor belt that carries the substrate below the stationary injector.

Embodiments are also relate to an apparatus for depositing material on a flexible substrate. The apparatus includes a set of pulleys, a stationary injector a scanning module and an enclosure. The set of pulleys wind or unwind the flexible substrate. The stationary injector injects a first precursor onto the flexible substrate. The scanning module moves across space between the stationary injector and the substrate to inject a second precursor onto the substrate. The enclosure encloses the flexible substrate susceptor and the scanning module.

### BRIEF DESCRIPTION OF DRAWINGS

Figure (FIG.) 1 is a cross sectional diagram of a scanning deposition device, according to one embodiment.

FIG. 2 is a perspective view of the scanning deposition device of FIG. 1, according to one embodiment.

FIG. 3 is a cross sectional diagram illustrating a scanning module, according to one embodiment.

FIG. 4A is a conceptual diagram illustrating a plasma source using coaxial lines, according to one embodiment.

FIG. 4B is a conceptual diagram illustrating diffuse coplanar surface barrier discharge (DCSBD) plasma source, according to one embodiment.

FIGS. 5A through 5E are diagrams illustrating sequential movements of scanning modules across the substrate, according to one embodiment.

FIG. 6A is a perspective view of a monolithic scanning module, according to one embodiment.

FIG. 6B is a cross sectional diagram of the monolithic scanning module of FIG. 6A, according to one embodiment.

FIG. 6C is a detailed view of a section of the monolithic scanning module of FIG. 6A, according to one embodiment.

FIG. 7 is a perspective view of the monolithic scanning module mounted on plenum structures, according to one embodiment.

FIG. 8A through 8C are diagrams illustrating movement of the monolithic scanning module across a substrate, according to one embodiment.

FIG. 9 is a diagram illustrating components for discharging source precursor, according to one embodiment.

FIGS. 10A and 10B are diagrams illustrating a conveyor belt system for processing multiple substrates, according to one embodiment.

FIG. 11 is a diagram illustrating performing an atomic layer deposition (ALD) process on a film, according to one embodiment.

### DETAILED DESCRIPTION OF EMBODIMENTS

Embodiments are described herein with reference to the accompanying drawings. Principles disclosed herein may, however, be embodied in many different forms and should not be construed as being limited to the embodiments set forth herein. In the description, details of well-known features and techniques may be omitted to avoid unnecessarily obscuring the features of the embodiments.

In the drawings, like reference numerals in the drawings denote like elements. The shape, size and regions, and the like, of the drawing may be exaggerated for clarity.

Embodiments relate to a deposition device for depositing one or more layers of material on a substrate using scanning modules that move across the substrate in a chamber filled with reactant precursor. The substrate remains stationary during the process of depositing the one or more layers of material. The chamber encloses the substrate and the scanning modules. The chamber is filled with reactant precursor to expose the substrate to the reactant precursor. As the scanning modules move across the substrate, the scanning modules remove the reactant precursor in their path and/or revert the reactant precursor to an inactive state. The scanning modules also inject source precursor onto the substrate as the scanning modules move across the substrate to form a layer of material on the substrate by an atomic layer deposition (ALD) process.

Figure (FIG.) 1 is a cross sectional diagram of a scanning deposition device 100, according to one embodiment. The scanning deposition device 100 deposits one or more layer of material on a substrate 120 by performing atomic layer deposition (ALD) processes. The scanning deposition device 100 may include, among other components, a chamber wall 110 forming a chamber 114, a reactant injector 136, a discharge port 154, and a radical generator 138 connected to the reactant injector 136. The chamber 114 encloses susceptor 128 and scanning modules 140A through 140D (hereinafter collectively referred to as “the scanning modules 140”). The scanning deposition device 100 may also include additional components not illustrated in FIG. 1 such as mechanism for lifting and moving the substrate 120 through opening 144.

The reactant injector 136 injects reactant precursor into the chamber 114. In one embodiment, the reactant injector 136 may be embodied as a showerhead that injects the reactant precursor above the substrate 120 in a relatively consistent manner across the entire substrate 120. As illustrated in FIG. 1, the reactant injector 136 may be placed above the substrate 120 so that the reactant precursor is present at higher concentration above the substrate 120 along the path that the scanning modules 140 moves across the substrate 120. The reactant precursor is, for example, radicals generated in the radical generator 138, as described below in detail with reference to FIGS. 4A and 4B. The reactant precursor injected into the chamber 114 may be discharged via the discharge port 154 in the direction shown by arrow 156.

The susceptor 128 receives the substrate 120 and is supported by a pillar 118 that provides support. The pillar 118 may include pipes and other components (not shown) to provide source precursor to the scanning module 140 as well as convey excess source precursor and/or purge gas to the scanning modules 140. The susceptor 128 may further include heaters or coolers (not shown) to control the temperature of the substrate 120. The susceptor 128 may be formed with pathways 150 at the left and right ends where the scanning modules 140 may seat idle. The pathways 150 may partially discharge the source precursor or purge gas injected by the scanning modules 140 via the discharge port 154 or via a separate port (not shown).

The opening 144 enables the substrate 120 to be moved into or out of the chamber 114 using, for example, a robot arm or other actuators. The opening 144 can be closed during the deposition process so that gas remains within the chamber 114 at a desired pressure.

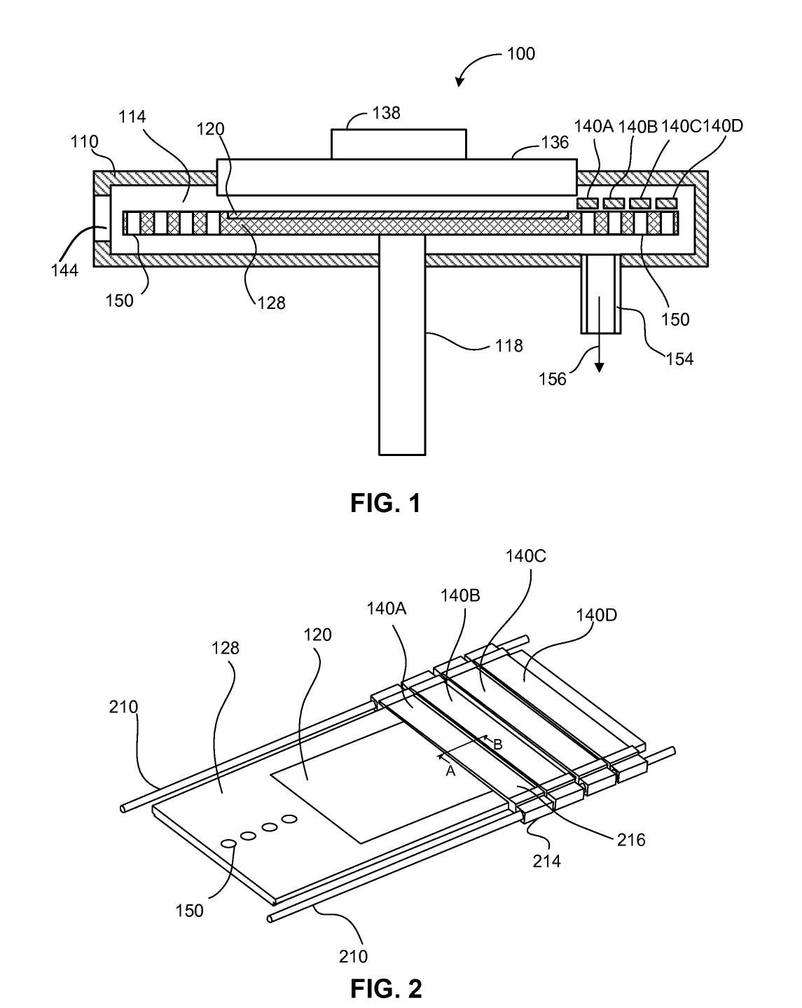

FIG. 2 is a perspective view of a scanning deposition device 100, according to one embodiment. The scanning modules 140 are mounted on rails 210 at both sides. Each of the scanning modules 140 includes a linear motor 214 that moves the scanning module 140 along the rails 210. For this purpose, electric power may be provided to the linear motor 214 through cables (not shown).

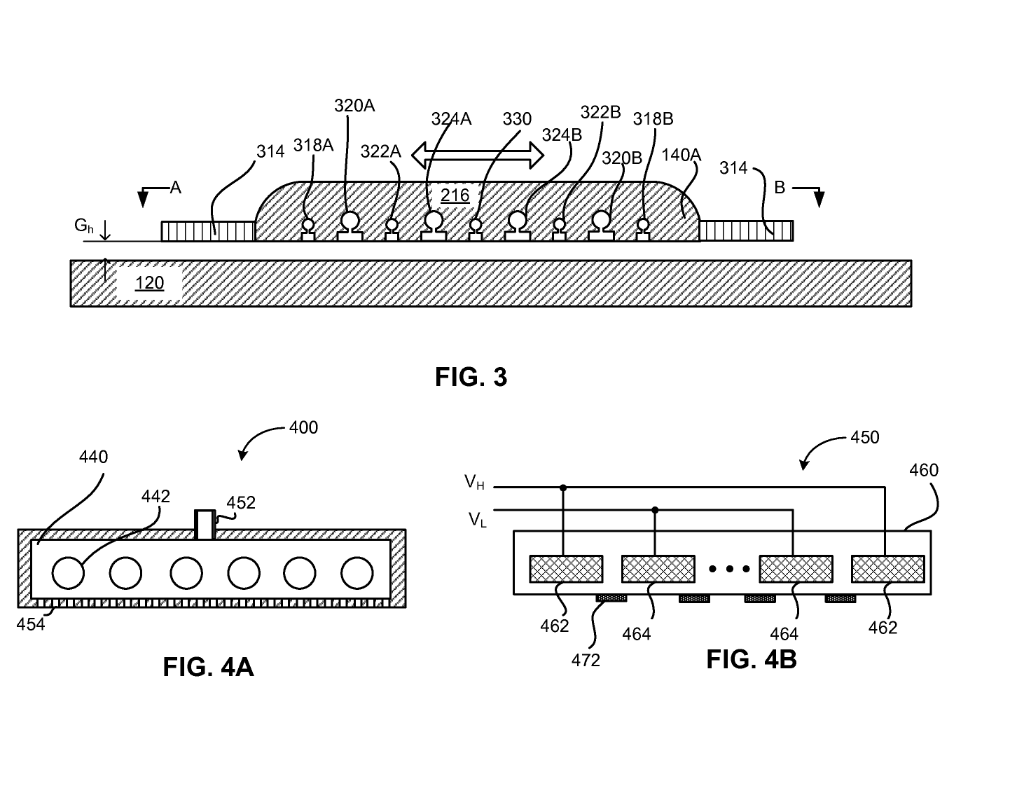

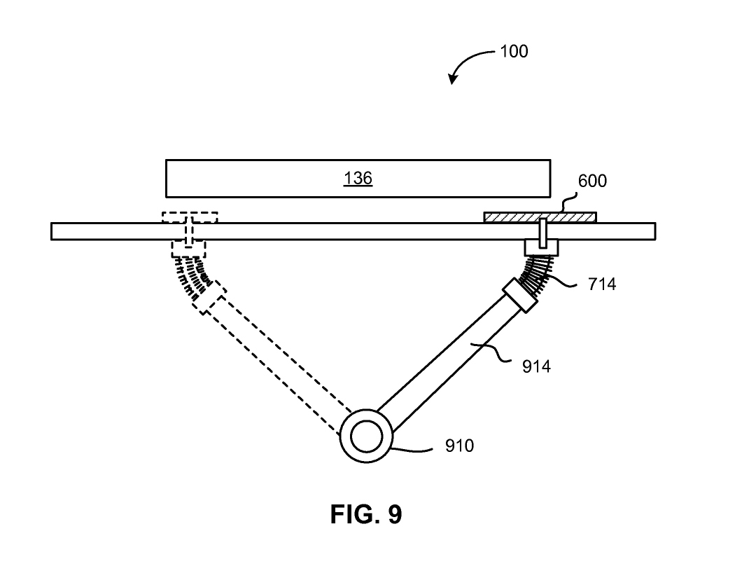

A body 216 of the scanning module 140 extends between the two linear motors 214. The body 216 is formed with injectors for injecting the source precursor and purge gas, and exhaust cavities for discharging excess gases, as described below in detail with reference to FIG. 3. The body 216 is also connected to pipes for carrying the precursor, purge gas and discharge gas from sources external to the scanning deposition device 100. The pipes may be flexible so that the pipes maintain contact with the scanning modules, as described below in detail with reference to FIG. 9.

FIG. 3 is a cross sectional diagram of a scanning module 140A taken along line A-B of FIG. 2, according to one embodiment. The scanning module 140A may include, among other components, the body 216 and neutralizers 314. When the reactant precursor is radicals (e.g., O* radicals and/or (OH)* radicals), the neutralizers 314 function to render reactant coming into contact inactive. As the positively-charged ions strike the substrate generated by the plasma come into contact with the substrate 120, the substrate 120 is charged positively charged. In order to neutralize the charge of the ions, the neutralizer 314 is provided. The neutralizer 314 is charged with polarity opposite to the ions (e.g., negatively-charged) so that the charged precursor near the substrate surface is neutralized. In this way, buildup of electrostatic charge on the substrate surface can be prevented.

In the embodiment of FIG. 3, the lower portion of the body 216 is formed sequentially with a purge gas injector 318A, a reactant gas exhaust 320A, a separation purge gas injector 322A, a source exhaust 324A, a source injector 330, a source exhaust 324B, a separation purge gas injector 322B, a reactant exhaust 320B and a purge gas injector 318B. The purge gas injectors 318A, 318B inject purge gas (e.g. Argon gas) onto the substrate 120 to remove the excess source precursor or reactant precursor that may remain on the substrate 120. The excess precursor may be precursor physisorbed on the substrate 120.

The reactant gas exhausts 320A, 320B discharge the reactant precursor entering below the body 216. The separation purge gas injectors 322A, 322B inject purge gas to prevent the reactant precursor from coming into contact with the source precursor injected by the source injector 330 as well as removing any excess material formed by the reaction between the source precursor and the reactant precursor (e.g., physisorbed material on the substrate 120). The source injector 330 injects the source precursor onto the substrate 120. The purge gas injectors 318A, 318B, the reactant gas exhausts 320A, 320B, the separation purge gas injectors 322A, 322B, source exhausts 324A, 324B, and the source injector 330 may be connected to channels or pipes that carry gases to or from components outside the scanning deposition device 100.

The reactant precursor entering through a gap between the substrate 120 and the scanning module 140A is first neutralized by the neutralizers 314, and then discharged via the reactant exhausts 320A, 320B.

The substrate 120 is first adsorbed with the reactant precursor when the chamber 114 is filled with the reactant precursor. Then, the scanning module 140A moves over the substrate, removing excess reactant precursor the purge gas injected by the purge gas injector 318A, 318B. The source injector 330 of the scanning module 140A subsequently injects source precursor that comes into contact with the reactant precursor chemisorbed on the substrate 120 to form a layer of material on the substrate 120. Excess material formed as a result of the reaction between the reactant precursor and the source precursor is removed by the purge gas injected by the separation purge gas injectors 322A, 322B.

In an alternative embodiment, the locations of the purge gas injectors 318A, 318B are switched with the locations of the reactant gas exhausts 320A, 320B. That is, the reactant gas exhausts 320A, 320B may be formed at outermost bottom portions of the body 216.

The body 216 may have a plat profile that is aerodynamic. Such aerodynamic profile of the body 216 is advantageous, among other reasons, because (i) agitation or turbulence of the reactant precursor filling the chamber 114 can be reduced, and (ii) nitrogen or hydrogen radicals having short life-span can be effectively used to deposit, for example, nitride films or metal films.

FIG. 4A is a conceptual diagram illustrating a plasma source 400 using coaxial electrodes 442, according to one embodiment. The plasma source 400 may be used as the radical generator 138 to generate radicals as the reactant precursor. The coaxial electrodes 442 extend across either the length or widths of the plasma source 400. When gas is injected into the plasma source 400 via an inlet 452 and electric signals are applied to the coaxial electrodes 442, radicals of the gas are generated. The generated radicals may be provided to the reactant injector 136 via outlets 454. The reactant injector 136 then distributes the radicals over the substrate 120.

FIG. 4B is a conceptual diagram illustrating diffuse coplanar surface barrier discharge (DCSBD) plasma source 450, according to one embodiment. The DCSBD plasma source 450 includes a dielectric block 460 with electrodes 462, 464 placed therein. The electrodes 462 are connected to a high supply voltage, and the electrodes 464 are connected to the low supply voltage. Plasma 472 is formed on the surface of the dielectric block 460 between the electrodes 462, 464, which generate radicals of gas surrounding the dielectric block 460. The generated radicals may be used as the reactant precursor injected via the reactant injector 136.

The plasma source described above with reference to FIGS. 4A and 4B are merely illustrative. Other types of plasma sources may also be employed to generate radicals for use in the scanning deposition device 100. Alternatively, no plasma source may be used at all. The reactant precursor used in the scanning deposition device 100 may be a gas that does not involve the use of any plasma sources.

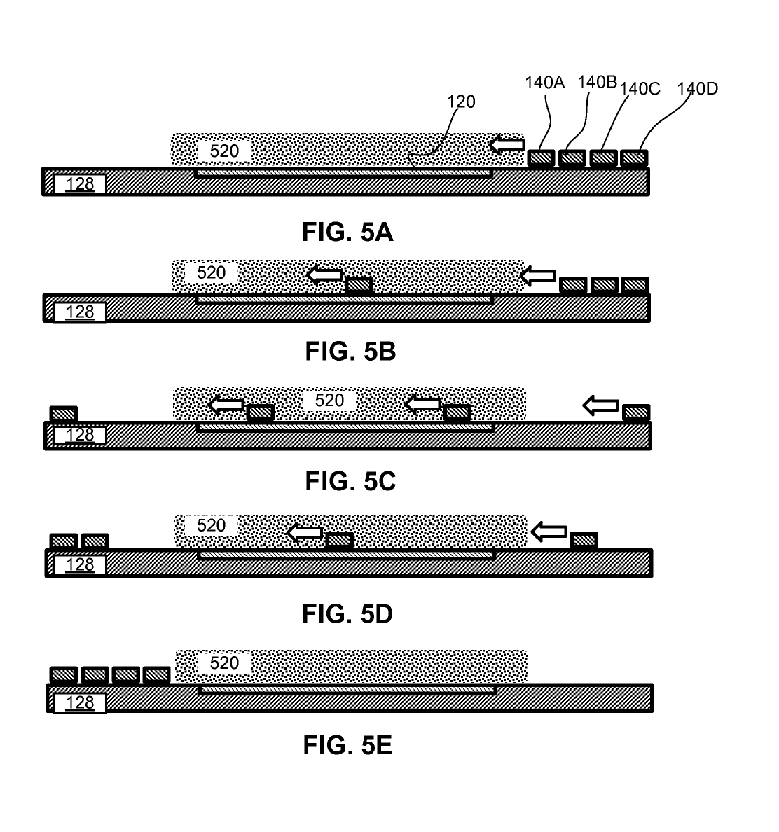

FIGS. 5A through 5E are diagrams illustrating sequential movements of scanning modules 140 across the substrate 120, according to one embodiment. Reactant precursor 520 is injected over the substrate 120 and the susceptor 128. As a result, the reactant precursor is adsorbed onto the substrate 120. As shown in FIGS. 5A and 5B, the scanning module 140A moves from the right to the left over the substrate 120 while discharging the reactant precursor below the scanning module 140A and injecting the source precursor onto the substrate 120. On the other hand, the substrate 120 remains in a stationary position on the susceptor 128. As a result of moving the scanning module 140A, a layer of material is formed on the substrate 120 by an ALD process.

In one embodiment, the scanning module 140B starts to move towards the left while the scanning module 140A is passing over the substrate 120, as shown in FIG. 5B. The scanning modules 140A and 140B may both be passing over different parts of the substrate 120 as shown in FIG. 5C. The scanning modules 140C, 140D also move to the left sequentially as shown in FIGS. 5D and 5E. In other embodiments, the scanning modules may start to move towards left after a previous scanning module completes the traversing of the substrate 120.

Each of the scanning modules 140A through 140D may inject the same or different source precursor on the substrate. For example, all of the scanning modules 140A through 140D may inject trimethylaluminum (TMA) onto the substrate 120. In a different example, the scanning module 140A injects TMA, the scanning module 140B injects TriDiMethylAminoSilane (3DMASi), the scanning module 140C injects, TetraEthylMethylAminoTitanium (TEMATi), and the scanning module 140D injects TetraEthylMethylAminoZirconium (TEMAZr) as source precursor. After the four scanning modules 140A through 140D passes over the substrate 120, atomic layers of Al₂O₃/SiO₂/TiO₂/ZrO₂ are formed on the substrate 120.

In one embodiment, the scanning module 140A passes “i” number of times over the substrate 120 before the scanning module 140B passes “j” number of times over the substrate 120. Then, the scanning module 140C passes “k” number of times over the substrate 120, and the scanning module 140D passes “l” number of times over the substrate 120. In this way, a composite layer including “i” layers of Al₂O₃), “j” layers of SiO₂, “k” layers of TiO₂ and “l” layers of ZrO₂ may be formed on the substrate 120.

One or more of the scanning modules 140 may intermittently inject the source precursor to deposit one or more layers on only certain regions of the substrate 120. Moreover, the scanning modules 140 may include shutters (not shown) that inject the source precursor only at certain locations of the substrate 120. By intermittently injecting the source precursor and/or operating the shutters, selective regions of the substrate 120 may be deposited with one or more layers of material or deposited with materials of different thickness at different regions of the substrate 120. Also, the scanning modules 140 may reciprocate over a selected region of the substrate 120 to increase the thickness of the deposited material or selectively deposit materials on the selected region. Such selective deposition of materials can be performed by the scanning deposition device 100 without using a shadow mask or etching. Therefore, the scanning deposition device 100 enables patterned of materials on substrates that may not suitable for etching processes (e.g., substrate made of bioactive substances).

In one or more embodiments, the scanning modules 140 inject the source precursor when passing over the substrate 120 but the scanning module 140 stops injecting the source precursor after the scanning module 140 passes over to portions of the susceptor 128 where the substrate 120 is not mounted. After the scanning modules 140 stops moving (as shown in FIG. 5E), the plasma source 138 may be turned off, and the injection of the purge gas may also be turned off. Then the substrate 120 may be removed from the chamber 114 via the opening 144.

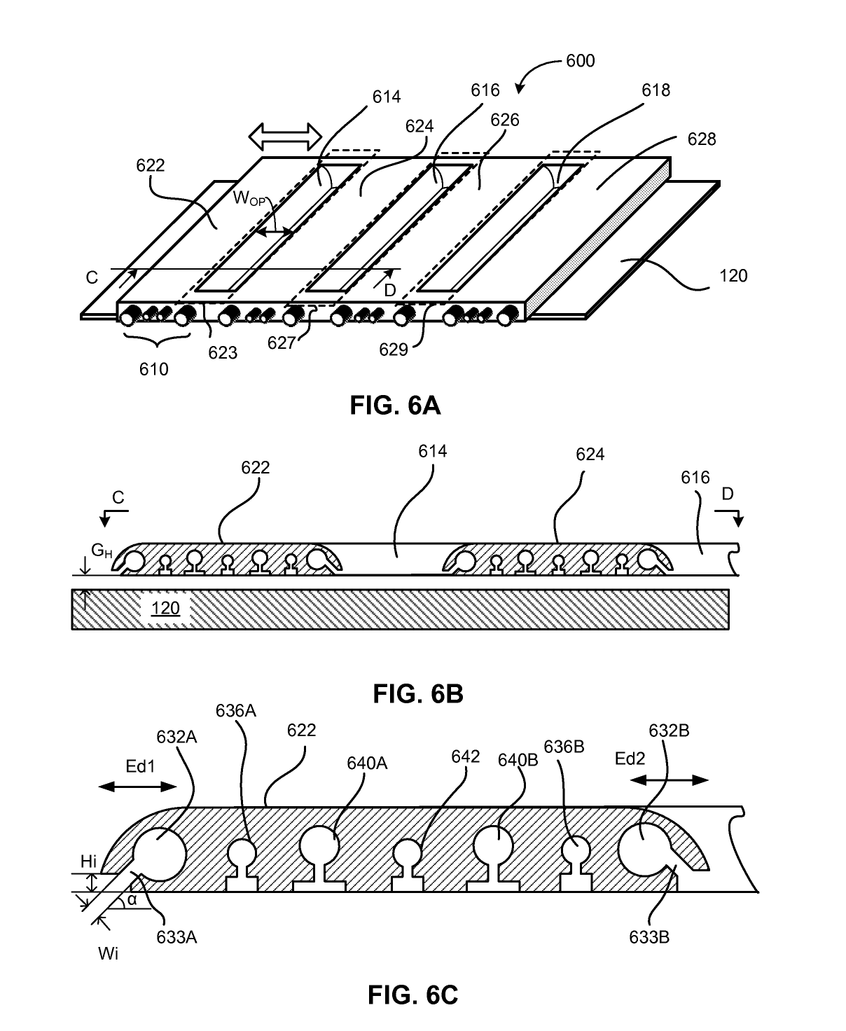

FIG. 6A is a perspective view of a monolithic scanning module 600, according to one embodiment. The monolithic scanning module 600 may include multiple bodies 622, 624, 626, 628 connected by bridge portions 623, 627, 629. Each of the bodies 622, 624, 626, 628 includes purge gas injectors, reactant gas exhausts, source exhausts and a source injector, for example, in the arrangement as described below in detail with reference to FIG. 6C. The bodies 622, 624, 626, 628 and the bridge portions 623, 627, 629 move together over the susceptor or substrate 120.

Each of the bridge portions 623, 627, 629 is formed with opening 614, 616, 618 to expose the substrate 120 to the reactant precursor. Assuming that width of an opening is W_{OP} and the speed of the monolithic scanning module 600 is V_{M}, the substrate 120 is exposed to the reactant precursor by time W_{OP}/V_{M}.

As the monolithic scanning module 600 moves across the substrate 120, the substrate is repeatedly exposed to reactant precursor and source precursor. Each bodies 622, 624, 626, 628 of the scanning module 600 may inject the same of different source precursor to deposit different materials on the substrate 120.

Each of the bodies 622, 624, 626, 628 may be connected via flexible tubes 610 to receive or discharge gases. Ferrofluidic rotary seals may be provided between the bodies 622, 624, 626, 628 and the flexible tubes 610 to prevent leakage of the gases conveyed via the flexible tubes 610.

FIG. 6B is a cross sectional diagram of the monolithic scanning module 600 taken along line C-D of FIG. 6A, according to one embodiment. The scanning module 600 moves across the substrate 120 while maintaining a gap of G_{H}.

FIG. 6C is a detailed view of the body 622 of the monolithic scanning module of FIG. 6A, according to one embodiment. The body 622 is formed with reactant gas exhausts 632A, 632B, purge gas injectors 636A, 636B, source exhausts 640A, 640B, and a source injector 642. Functions and structures of these injectors and exhausts are substantially the same as described above with reference to FIG. 3 except for the reactant exhausts 632A, 632B.

Leading or trailing edges Ed1, Ed2 of bodies 622, 624, 626, 628 may have curved upper surface as shown in FIGS. 6B and 6C. The curved profile of the edges Ed1, Ed2 may be a horn shape. Such shape advantageous facilitates entry of the reactant precursor through the openings 614, 616, 618. When using radicals as the reactant precursor, the top surface of the entire monolithic scanning module 600 or the top surfaces of edges Ed1, Ed2 may be coated with dielectric material (e.g., Al₂O₃) or quartz to prevent the radicals from contacting the top surfaces and reverting to an inactive state.

The reactant gas exhausts 632A, 632B have inlets 633A, 633B that are slanted at an angle of a relative to the top surface of the substrate 120. Further, the inlets 633A, 633B has a width of Wi and has horizontally raised portion of height Hi. By adjusting the width Wi, height Hi and the angle α, discharging of the reactant gas can be tuned.

The reactant gas exhaust adjacent to the opening (e.g., the reactant gas exhaust 632B) may also promote the exposure of a portion of the substrate below the opening 614. That is, the reactant gas exhaust 632B may promote relatively consistent flow of the reactant precursor gas across the length of the opening 614 so that materials are deposited in a uniform manner on the substrate 120. In one embodiment, each of the bodies 622, 624, 626, 628 may have different configurations of width Wi, height Hi and the angle α depending on the source precursor injected by the bodies 622, 624, 626, 628 or the location of the bodies within the monolithic scanning module 600.

Although not illustrated in FIGS. 6B and 6C, the bodies 622, 624, 626, 628 may be further formed with one or more separation purge gas injectors to prevent mixing of the reactant precursor and the source precursor in areas other than on the top surface of the substrate 120.

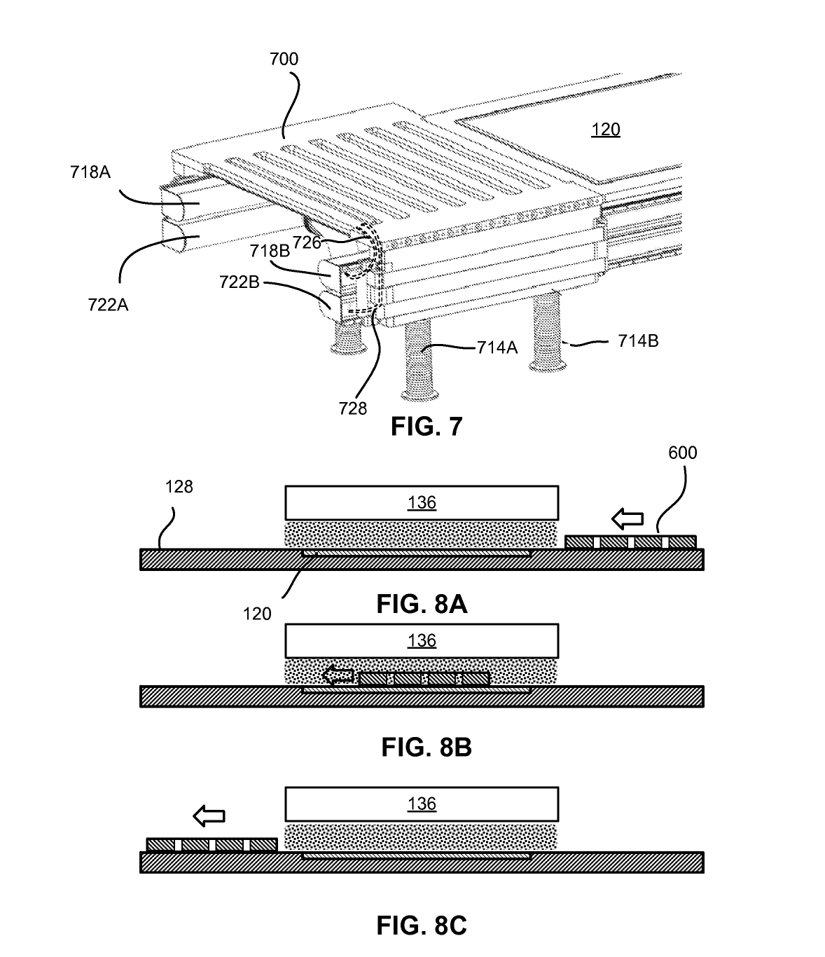

FIG. 7 is a perspective view of the monolithic scanning module 700 mounted on plenum structures 718, 722, according to one embodiment. The scanning module 700 includes more bodies and bridge portions compared to the scanning module 600 of FIG. 6A. The reactant exhausts of the bodies are connected by conduits (e.g., conduit 726) at one end to upper plenum structures 718. The source exhausts are connected by different conduits (e.g., conduit 728) to lower plenum structures 722. The upper plenum structure 718B and the lower plenum structure 722B are connected to separate pipes 714A, 714B, respectively. In this way, the source precursor and the reactant precursor are discharged from the scanning deposition device 100 via different routes. By preventing mixture of the source precursor and the reactant precursor during discharge, less particles are likely to be formed due to the reaction of the source precursor and the reactant precursor.

Although not illustrated in FIG. 7, conduits (not shown) connect the upper plenum structure 718A and the lower plenum structure 722A to the other end of the scanning module 700 so that the source precursor and the reactant precursor can be discharged more uniformly across the bodies.

The plenum structures 718, 722 may be mounted with rails that support the monolithic scanning module 700 to slide across the substrate 120 and the susceptor.

FIGS. 8A through 8C are diagrams illustrating movement of the monolithic scanning module 600 across the substrate 120, according to one embodiment. In this example, the monolithic scanning module 600 starts the movement from the right end (see FIG. 8A), moves across the substrate 120 (see FIG. 8B) and the finishes the movement after moving to the left end (see FIG. 8C). As the source precursor is injected by the bodies of the monolithic scanning module 600, layers of material are deposited on the substrate 120.

The monolithic scanning module 600 may repeat left and right movement to deposit materials to desired thicknesses. Also, the injection of source precursor may be switched on at certain locations on the substrate 120 to deposit the materials in a predetermined pattern.

FIG. 9 is a diagram illustrating components of the scanning deposition device 100 for discharging source precursor, according to one embodiment. The source exhausts formed in the scanning module 600 are connected via an angular displacement bellow 714 and a compression bellows 914 to an exhaust pipe 910. The angular displacement bellows 714 is structured to flex to different angles to provide connection between the compression bellows 914 and the scanning module 600. The compression bellows 914 is structured to change its length. The angular displacement bellows 714 and the compression bellows 914 provide path from the scanning module 600 to the exhaust pipe 910 despite different locations of the scanning module 600 on the susceptor.

Ferrofluidic rotary seal may be provided between the exhaust pipe 910 and the compression bellows 914 so that the source precursor is conveyed to the exhaust pipe 914 without leaking even as the compression bellows 914 rotates about the exhaust pipe 910. Various other structures may be provided to discharge the source precursor from the scanning deposition device 100. Further, although bellows 714, 914 for carrying only the source precursor are illustrated in FIG. 9, another set of bellows may be provided to discharge the reactant precursor.

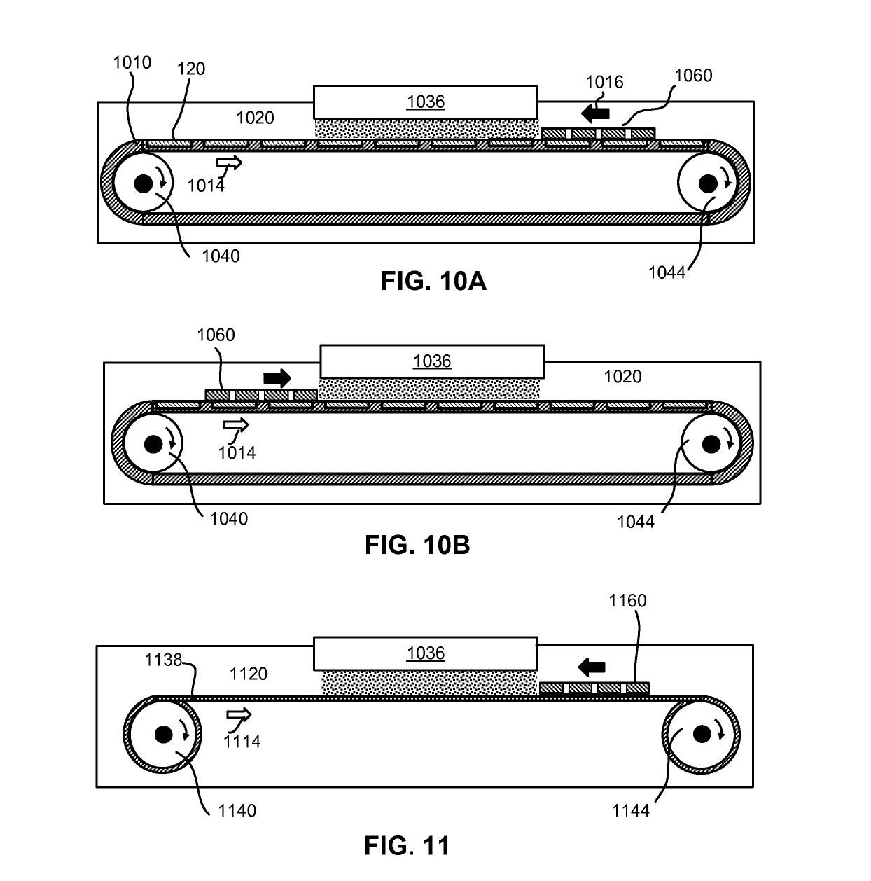

FIGS. 10A and 10B are diagrams illustrating a conveyor belt system for processing multiple substrates 120, according to one embodiment. Pulleys 1040, 1044 are placed within a chamber 1020 that is filled with reactant precursor by reactant injector 1036. A belt 1010 is suspended between the pulleys 1040, 1044. A plurality of substrates 120 are secured to the belt 1010. As the pulleys 1040, 1044 are rotated, the belt 1010 is moved along with the substrates 120 from the left to the right, as shown by arrow 1014. FIGS. 10A and 10B illustrate scanning module 1060 at the right end and the left end, respectively.

A scanning module 1060 moves from the right to the left as shown by arrow 1015. The substrates 120 are exposed to the reactant precursor injected by the reactant injector 1036 and then exposed to the source precursor injected by the scanning module 1060. The linear speed of the belt 1010 is slower than the speed of the scanning module 1060 so that the scanning module 1060 can pass over the substrates 120 while the substrates 120 are passing under the reactant injector 1036. The scanning module 1060 may move over the substrates 120 more than once while the substrates 120 are below the reactant injector 1036 to deposit a thicker film on the substrates.

Although the scanning module 1060 in FIGS. 10A and 10B is illustrated as a monolithic scanning module with multiple bodies, scanning modules with a single body as described above in detail with reference to FIG. 3 may also be used.

After a substrate reaches the right end, the substrate may be removed from the conveyor belt system and an additional substrate may be placed on the left end to undergo the deposition process.

FIG. 11 is a diagram illustrating a continuous processing system for performing an atomic layer deposition (ALD) process on a flexible film 1138, according to one embodiment. As the film 1020 is unwound from a pulley 1140 and wound onto a pulley 1144 within a chamber 1120, the flexible film 1138 moves in the direction as indicated by arrow 1114. The scanning module 1160 moves over the film 1138 while the reactant injector 1036 injects reactant precursor onto the film 1138. The portion of the film 1120 deposited with the material is wound onto the pulley 1144.

The language used in the specification has been principally selected for readability and instructional purposes, and may not have been selected to delineate or circumscribe the inventive subject matter. Accordingly, the embodiments described herein are intended to be illustrative, but not limiting the inventive subject matter.

1. An apparatus for depositing material on a substrate, comprising:
a susceptor configured to secure one or more substrates;
a stationary injector configured to inject a first precursor onto the one or more substrates;
a scanning module configured to move across space between the stationary injector and the one or more substrates to inject a second precursor onto the one or more substrates; and
an enclosure configured to enclose the susceptor and the scanning module.

2. The apparatus of claim 1, further comprising at least another scanning module configured to move across the space between the stationary injector and the one or more substrates to inject a third precursor onto the one or more substrates.

3. The apparatus of claim 1, wherein the scanning module is formed with:
a first gas exhaust configured to discharge the first precursor between the scanning module and the one or more substrates;
a gas injector configured to inject the second precursor onto the one or more substrates; and
a second gas exhaust configured to discharge excess second precursor remaining after injection onto the one or more substrates.

4. The apparatus of claim 3, wherein the scanning module is further formed with a purge gas injector configured to inject purge gas to remove physisorbed second precursor from the one or more substrates.

5. The apparatus of claim 4, wherein the purge gas further prevents the second precursor from coming into contact with the first precursor in areas other than on the one or more substrates.

6. The apparatus of claim 1, wherein the first precursor is reactant precursor for performing atomic layer deposition, and the second precursor is source precursor for performing the atomic layer deposition.

7. The apparatus of claim 1, further comprising a radical generator connected to the stationary injector to generate radicals of gas as reactant precursor.

8. The apparatus of claim 7, wherein the scanning module further comprises one or more neutralizers at least at a leading edge or a trailing edge to render the radicals of gas inactive.

9. The apparatus of claim 1, wherein the scanning module comprise a plurality of bodies formed with a gas injector to inject gas onto the one or more substrates, the bodies connected by bridge portions, each of the bridge portions formed with an opening to expose the one or more substrates to the first precursor.

10. The apparatus of claim 9, wherein each of the bodies is formed with a first precursor exhaust slanted towards the opening to discharge the first precursor entering through the opening.

11. The apparatus of claim 9, wherein an upper surface of each of the bodies is curved towards a bottom surface of the body at an edge adjacent to the opening.

12. The apparatus of claim 9, wherein each of the bodies is formed with:
a first gas exhaust configured to discharge the first precursor between the scanning module and the one or more substrates;
a gas injector configured to inject the second precursor onto the one or more substrates; and
a second gas exhaust configured to discharge excess second precursor remaining after injection onto the one or more substrates.

13. The apparatus of claim 1, wherein the one or more substrates remain stationary during injection of the first precursor or the second precursor.

14. The apparatus of claim 1, wherein the susceptor is formed with pathways at both ends to discharge the second precursor injected onto the susceptor by the scanning module.

15. The apparatus of claim 1, further comprising one or more rails upon which the scanning modules slide across the one or more substrates.

16. The apparatus of claim 1, wherein the susceptor is a conveyor belt configured to carry the substrate across the stationary injector.

17. An apparatus for depositing material on a flexible substrate, comprising:
a set of pulleys configured to wind or unwind the flexible substrate;
a stationary injector configured to inject a first precursor onto the flexible substrate;
a scanning module configured to move across space between the stationary injector and the substrate to inject a second precursor onto the substrate; and
an enclosure configured to enclose the flexible substrate susceptor and the scanning module.

18. The apparatus of claim 17, wherein the scanning module is formed with:
a first gas exhaust configured to discharge the first precursor between the scanning module and the one or more substrates;
a gas injector configured to inject the second precursor onto the one or more substrates; and
a second gas exhaust configured to discharge excess second precursor remaining after injection onto the one or more substrates.

19. The apparatus of claim 18, wherein the scanning module is further configured with a purge gas injector configured to inject purge gas to remove physisorbed second precursor from the one or more substrates.

20. The apparatus of claim 17, wherein the first precursor is reactant precursor for performing atomic layer deposition, and the second precursor is source precursor for performing the atomic layer deposition.
